(19) United States
(12) Patent Application Publication
(10) Pub. No.: US 2019/0042365 A1
(43) Pub. Date: Feb. 7, 2019

(54) READ-OPTIMIZED LAZY ERASURE CODING

(71) Applicant: Intel Corporation, Santa Clara, CA (US)

(72) Inventors: Kimberly A. MALONE, San Jose, CA (US); Steven C. MILLER, Livermore, CA (US)

(21) Appl. No.: 16/142,649

(22) Filed: Sep. 26, 2018

(51) Int. Cl. G06F 11/10; H03M 13/15

(52) U.S. Cl. CPC G06F 11/1076; H03M 13/154

(57) ABSTRACT

Examples include techniques for performing read-optimized lazy erasure encoding of data streams. An embodiment includes receiving a request to write a stream of data, separating the stream into a first plurality of extents, storing a primary replica and one or more additional replicas of each extent of the separated stream to a plurality of data storage nodes, and updating a list of extents to be erasure encoded. The embodiment further includes when an erasure encoded stripe can be created, getting the data for each of the extents of the erasure encoded stripe, calculating parity extents for unencoded extents of the erasure encoded stripe, writing the parity extents to a second plurality of data storage nodes, and deleting the one or more additional replicas of the extents of the erasure encoded stripe from the first plurality of data storage nodes.

### TECHNICAL FIELD

Examples described herein are generally related to techniques for storing and accessing data in storage devices in computing systems.

### BACKGROUND

Large data centers often use replication to provide data durability. This approach is straightforward but it comes at the cost of storage efficiency. The most common replication factor used is three, which means that storing X gigabytes (GB) of data durably requires 3× GB of storage. In very large data centers, the cost of this additional storage becomes significant.

Erasure coding (EC) is a method of data protection in which data is broken into fragments and encoded with redundant data pieces and stored across a set of different locations or storage media. Erasure codes convert input data into N outputs where any K<=N outputs can recover the data. Unlike replication, erasure codes allow greater fault tolerance with improved efficiency. A goal of erasure coding is to enable data that becomes corrupted at some point in the data storage process to be reconstructed by using information about the data that's stored elsewhere. Erasure coding is a forward error correction technology used to provide data resiliency and long-term data integrity, by spreading data blocks and parity information across multiple storage devices or systems that may be in multiple physical locations. Both the level of resiliency and where erasure coding is applied (at the array, at the node, or at the system level) can significantly affect how much processing overhead is consumed.

Erasure coding can be useful with large quantities of data and with applications or systems that need to tolerate failures, such as disk array systems, data grids, distributed storage applications, object stores and archival storage. One common use case for erasure coding is object-based cloud storage.

Erasure coding creates a mathematical function to describe a set of numbers so they can be checked for accuracy and recovered if one is lost. Referred to as polynomial interpretation or oversampling, this is the key concept behind erasure codes. In mathematical terms, the protection offered by erasure coding can be represented in simple form by the following equation: n=k+m. The variable “k” is the original amount of data or symbols. The variable “m” stands for the extra or redundant symbols that are added to provide protection from failures. The variable “n” is the total number of symbols created after the erasure coding process. For instance, in a 10 of 16 configuration, or EC 10/16, six extra symbols (m) would be added to the 10 base symbols (k). The 16 data fragments (n) (also known as strips) would be spread across 16 storage mediums, nodes or geographic locations. The original file could be reconstructed from 10 verified fragments.

Erasure coding can be used as an alternate approach to data replication to achieve data durability. Erasure coding has an effective replication factor of 1× to 2×, depending on the erasure coding parameters chosen (e.g., 1.4× for 10+4 erasure coding). The savings in storage efficiency are attractive, but they come at a cost. Erasure coding can cause decreased read and write performance, and greater system impact when there is a failure. In addition, it is problematic to convert existing data to erasure coding since this involves changing the on-disk data format.

Microsoft® Windows® Azure Storage (as described in “Erasure Coding in Windows Azure” by Cheng Huang, et al., published in the Proceedings of the 2012 USENIX conference on Annual Technical Conference, 2012) and Google® File System (as described in “Availability in Globally Distributed Storage Systems” by Daniel Ford, et al., published in the Proceedings of the 9th USENIX Symposium on Operating Systems Design and Implementation, USENIX, 2010) use “lazy” erasure coding to eliminate the write performance impact of erasure coding. In this approach, writes are performed as usual with triple replication. Erasure coding is then “lazily” done in the background. Once erasure coding is complete, the original replicas are deleted.

While this “lazy” erasure coding approach addresses the write performance impact, the approach does not address the negative impact on read performance of consolidating erasure-coded data fragments. The typical erasure coding approach also impacts on-disk data format, making the approach difficult to employ in data centers with existing data.

### BRIEF DESCRIPTION OF THE DRAWINGS

FIG. 1 illustrates an example of erasure coding.

FIG. 2 illustrates an example diagram of a storage architecture.

FIG. 3 illustrates an example storage cluster arrangement.

FIG. 4 illustrates an example extent write flow.

FIG. 5 illustrates an example read-optimized lazy erasure coding arrangement.

FIG. 6 illustrates an example encoding flow.

FIG. 7 illustrates an example server computing system.

FIG. 8 illustrates an example storage medium.

### DETAILED DESCRIPTION

As contemplated in the present disclosure, a read-optimized lazy erasure coding (ROLEC) comprises a process wherein data writes are replicated and then erasure coded in the background. Unneeded replicas are then freed asynchronously. Rather than breaking a single data write into fragments for erasure coding, multiple unrelated writes are collected and erasure coded. The erasure coded parity strips are stored, and then two of the three replicas are removed, leaving the original copy of the data intact for subsequent efficient reads.

Lazy erasure coding eliminates the negative write performance impact of erasure coding by performing erasure coding in the background. In addition, in embodiments of the present invention a full copy of data exists on one data storage node, allowing reads to be served from one storage device. This eliminates the fragmented read impact of erasure coding and preserves the existing on-disk data format. Because of elimination of data fragmentation, this technique can be applied to existing data, wherein the conversion is performed as a background process. Generally, embodiments of the present invention can be used with various types of erasure coding (e.g., Reed-Solomon (as described in I. Reed and G. Solomon, “Polynomial Codes Over Certain Finite Fields” Journal of the Society for Industrial and Applied Mathematics, volume 8, number 2, June 1960), and Local Reconstruction Codes (as described in “Erasure Coding in Windows Azure” by Cheng Huang, et al., published in the Proceedings of the 2012 USENIX conference on Annual Technical Conference, 2012), etc.). The choice of encoding will not affect the read and write performance improvements of the present system. As with any erasure coding system, each erasure coding type has unique characteristics with respect to performance during recovery from failures.

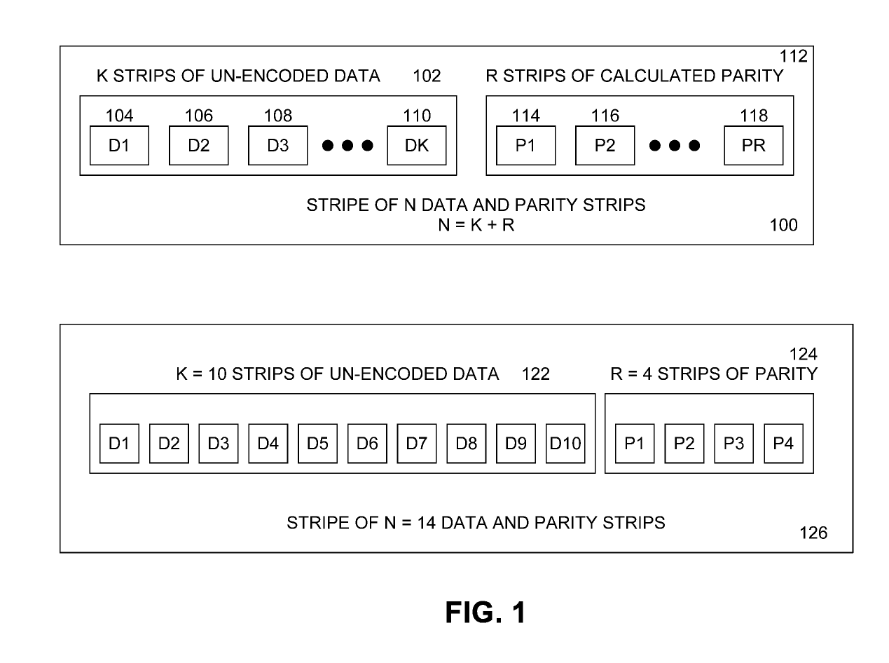

FIG. 1 illustrates an example of erasure coding. A stripe 100 for K+R erasure coding consists of N parts (also known as strips), where N=K un-encoded data units+R parity units, where N, K, and R are natural numbers. Thus, in this example K strips of un-encoded data units 102 includes data units D1 104, D2 101, D3 108, . . . DK 110, and R strips of calculated parity 112 includes parity units P1 114, P2 116, . . . PR 118. In an embodiment, the size of a data unit and the parity unit is implementation dependent (the size of the data units and the parity units are the same). FIG. 1 also shows an example of 10+4 erasure coding. In this example, stripe 126 has N=14, with K=10 un-encoded data units 122 and R=4 parity units 124.

As used herein, the term stream refers to a large sequence of data units. The term stream is used instead of file or volume to avoid the limitations and expectations that those terms imply. Streams are broken up into data units called extents. Each extent is of a fixed size. In one embodiment, an extent is 2 GB. Once an extent has been filled and is no longer changing, the extent is sealed, essentially declaring that the extent will no longer change.

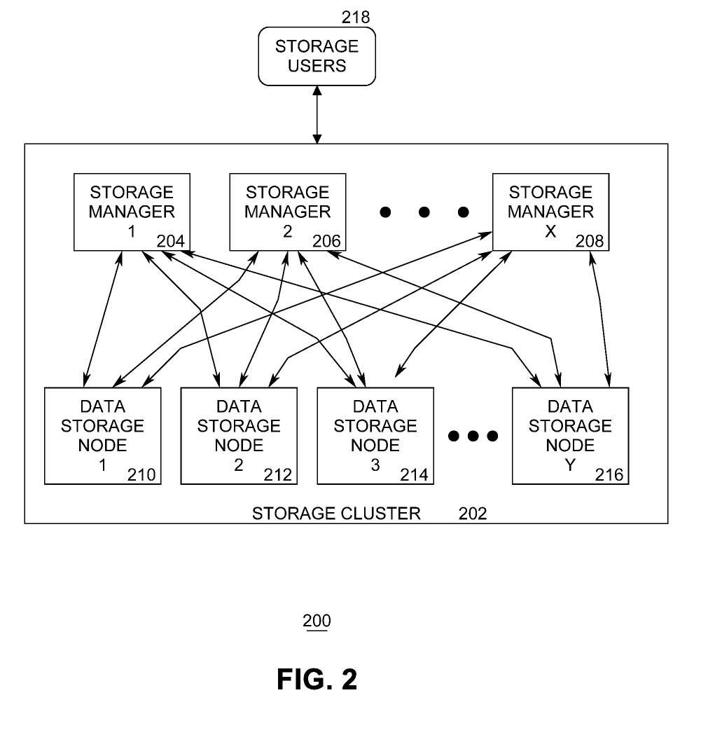

FIG. 2 illustrates an example diagram of a storage architecture 200. Storage users 218 send stream read and write requests to storage cluster 202. In an embodiment, storage users 218 are one or more of application programs, operating systems (OSs), virtual machines (VMs), or other software being executed by a computing platform either local to storage cluster 202 or coupled with storage cluster 202 over a network (such as the Internet, for example). Storage cluster 202 is composed of physical data storage nodes and one or more storage managers. In the example of FIG. 2, the data storage nodes are data storage node 1 210, data storage node 2 212, data storage node 3 214, . . . data storage node Y 216, where Y is a natural number. Each data storage node includes one or more storage devices to store data. The storage manager is a logical entity that handles stream requests, mapping to extents, and data protection of extents for a set of data storage nodes in storage cluster 202. In this example, the storage managers are storage manager 1 204, storage manager 2 206, . . . storage manager X 208, where X is a natural number. Storage cluster 202 contains one or many store managers, depending on how the storage cluster operator (e.g., a system administrator for a cloud data center) wants to segment their storage resources. Each storage manager couples to one or more data storage nodes as shown. In an embodiment, a storage manager does not necessarily couple to every data storage node in storage cluster 202. Each storage manager is coupled to data storage nodes across many fault domains, so that there is no single point of failure (SPOF). Each storage manager is durable and does not create a bottleneck for storage requests. In one embodiment, storage managers are implemented as software being executed on a computing platform. In another embodiment, storage managers are implemented as circuitry within data storage nodes 201, 212, 214, 216 of storage cluster 202.

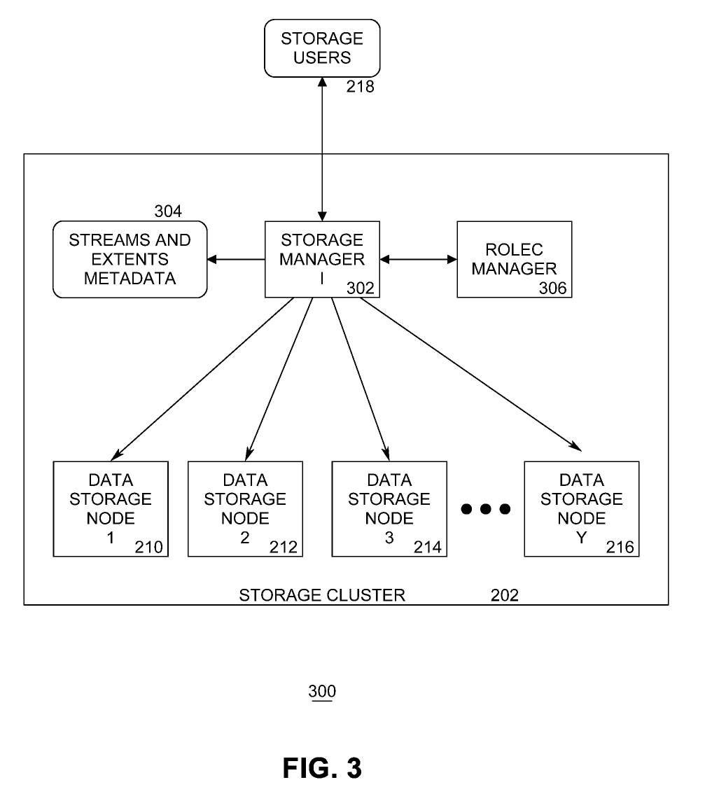

FIG. 3 illustrates an example storage cluster architecture 300. In this example, only one storage manager is included in order to simplify the description. However, it is understood from FIG. 2 that storage cluster 202 may include any number of storage managers. Storage manager I 302 (where I is in the range 1 . . . X of storage managers from FIG. 2) is coupled a plurality of data storage nodes as shown. In another embodiment, storage manager I is coupled to a subset of the data storage nodes shown in FIG. 3. In an embodiment, storage cluster 202 includes ROLEC manager 306 to coordinate read-optimized lazy erasure coding for data units stored in storage cluster 202. In one embodiment, ROLEC manager 306 is implemented as software being executed on a computing platform. In another embodiment, ROLEC manager 306 is implemented as circuitry within storage cluster 202. Storage manager I 302 is coupled with stream and extent metadata 304. Stream and extent metadata 304 include information describing the data units and parity units (e.g., stripes) stored in storage cluster 202.

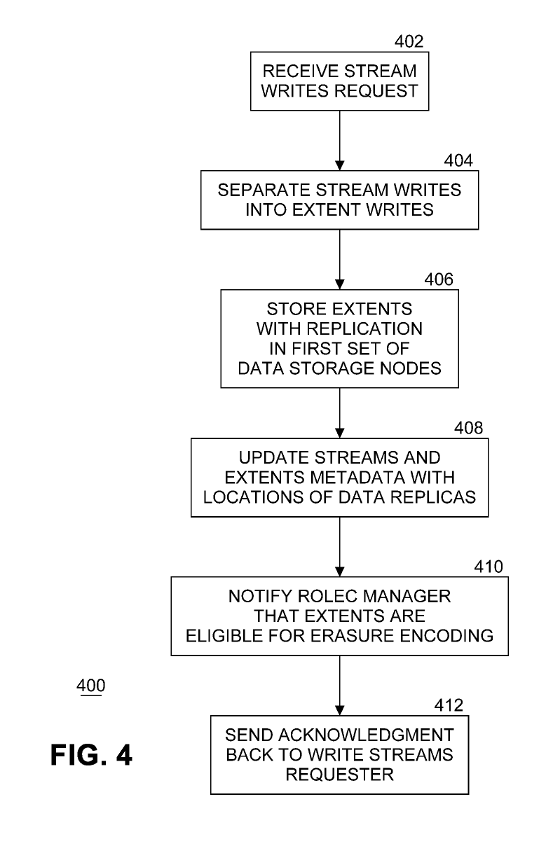

FIG. 4 illustrates an example extent write flow 400. At block 402 a stream write request is received by storage manager I 302 to store data from the stream. At block 404, storage manager I 302 separates the stream write into extent writes (e.g., writes of data units). At block 406, storage manager I 302 stores the extents with multiple replication across a first set of data storage nodes 210, 212, 214, . . . 216. That is, in an embodiment three replicas of the extents are stored (primary, secondary, and tertiary replicas), but no data storage node stores more than one replica of each extent. In another embodiment, only a secondary replica is used. In another embodiment, three or more replicas are used. In another embodiment, one or more additional replicas (other than the primary replica) are used. At block 408, storage manager I 302 updates streams and extents metadata 304 with locations of the replicas of the extents. At block 410 storage manager I 302 notifies ROLEC manager 306 that the extents are eligible for lazy erasure coding. In an embodiment, this notification is conditional on whether the stream has background erasure coding enabled. In an embodiment, this notification can be asynchronous and/or multiple asynchronous notifications of this type can be bundled together. At block 412, storage manager I 302 sends an acknowledgment back to the requester of the stream writes that the streams writes have been stored in storage cluster 202.

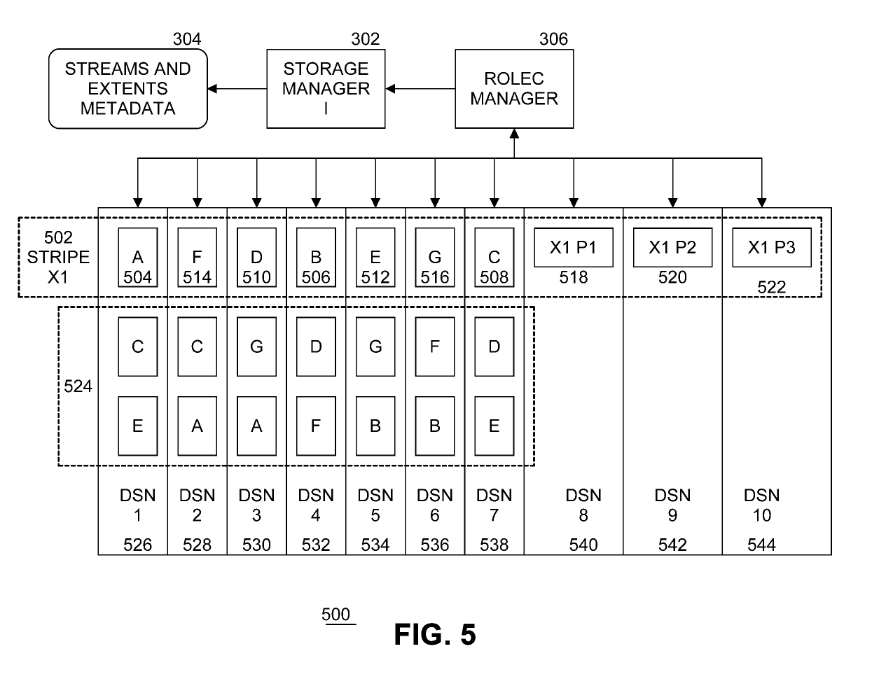

FIG. 5 illustrates an example read-optimized lazy erasure coding arrangement 500. This example shows 7+3 erasure coding, where stripe X1 502 has K of 7 extents (e.g., strips/extents A 504, B 506, C 508, D 510, E 512, F 514, and G 516), and R of 3 parity units (X1 P1 518, X1 P2 520, and X1 P3 522). In this example, stripe X1 502 has been stored according to block 406 of FIG. 4 across a plurality of data storage nodes as shown. For example, extent A 504 of stripe X1 502 has been stored on data storage node (DSN) 1 526, extent B 506 has been stored on DSN 4 532, extent C 508 has been stored on DSN 7 538, extent D 510 has been stored on DSN 3 530, extent E 512 has been stored on DSN 5 534, extent F 514 has been stored on DSN 2 528, and extent G 516 has been stored on DSN 6 536. Additional replicas 524 of the extents are distributed across data storage nodes so that no single data storage node stores multiple replicas of an extent.

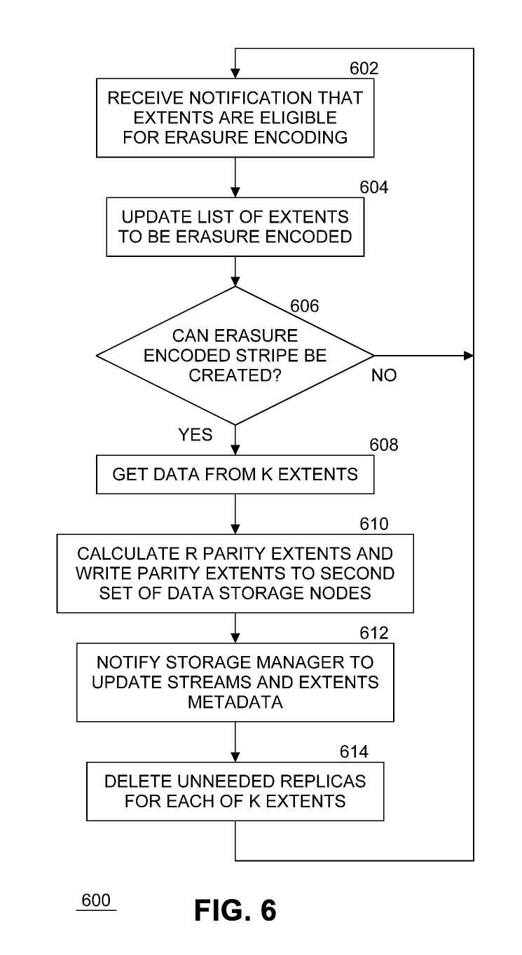

FIG. 6 illustrates an example encoding flow 600. At block 602, ROLEC manager 306 receives the notification from storage manager I 302 that extents are eligible for erasure encoding (sent at block 410 of FIG. 4). At block 604, ROLEC manger 306 updates a list of extents to be erasure encoded. In an embodiment, an alternative to storage manager I 302 notifying ROLEC manager 306 for every extent is to have the storage manager save information about eligible extents, and ROLEC manager 306 polls for this information periodically. At block 606, ROLEC manager 306 evaluates the list of extents to determine if an erasure encoded stripe can be created. In an embodiment, evaluation is performed periodically. In another embodiment, evaluation is performed when a notification is received. In still another embodiment, evaluation is performed when a plurality of notifications is received. In an embodiment, this evaluation is based on selection criteria that may include items such as whether each extent is stored on a different data storage node, and whether the data storage nodes used to store the extents are in different fault domains (based on rack, power, or other criteria). These criteria may be similar to those used when placement of the replicas was determined. In addition, stripes may or may not be restricted to extents from different streams. One requirement is that K extents are always required to create a stripe. ROLEC manager 306 identifies the K extents in order to trigger an encoding process. If no erasure encoded stripe can now be created, ROLEC manager 306 processing continues with waiting for further notifications at block 602. If an erasure encoded stripe can be created, ROLEC manager 306 at block 608 gets the data from the K extents stored in data storage nodes. ROLEC manager 306 then calculates the R parity extents for the K extents at block 610 and writes the R parity extents across a second set of data storage nodes. In an embodiment, the first set of data storage nodes is the same as the second set of data storage nodes. In another embodiment, the first set of data storage nodes is different than the second set of data storage nodes. In an embodiment ROLEC manager 306 chooses R different data storage nodes in different fault domains in storage cluster 202 from the K extents and writes the parity extents to these data storage nodes. At block 612, ROLEC manager 306 notifies storage manager I 302 to update streams and extents metadata 304 for each extent in the erasure encoded stripe to reflect what will be a single primary replica and where to read the extent (i.e., by reconstructing the extent using a subset of other extents in the stripe) if the primary location of the extent is unavailable.

At block 614 ROLEC manager 306 deletes replicas (e.g., secondary replicas (and possibly tertiary replicas, or additional replicas)) (K extents 524 of FIG. 5) for each of the K extents. ROLEC manager 306 then updates the list of extents to reflect the erasure encoding of the stripe. In an embodiment, ROLEC manager 306 “lazily” performs blocks 602 through 614 in the “background” (e.g., the notifications could all be stored in a message queue and the ROLEC manager only wakes up periodically to process the notifications in the queue). ROLEC manager 306 executes in a different processing thread than storage manager I 302.

The single remaining replica is available for servicing requests to read the extents during this process. When storage manager I 302 receives a request to read an extent of a stored stream, storage manager I 302 gets the read location from streams and extents metadata 304. Storage manager I 302 reads the extent from the specified location on a data storage node and returns the extent to the requester. If the extent cannot be read from the specified location (e.g., the data storage node is down, or the data at the specified location is corrupted, and so on), storage manager I 302 must reconstruct the extent based at least in part on other extents and parity extents. Information about the locations of the extent and parity data needed to perform the reconstruction for this extent of the stripe is stored in streams and extents metadata 304. Accordingly, storage manager I 302 reads data extents and parity extents from data storage nodes that are needed to reconstruct the requested extent. Storage manager I 302 reconstructs the extent and returns the extent to the requester. In an embodiment, storage manager I 302 determines whether this reconstructed extent should be stored as a replacement for the unavailable primary extent, by writing the reconstructed extent to a data storage node and updating the streams and extents metadata 304 to point to the new location of the primary extent.

The storage efficiency of this system is that of K+R erasure coding, where R parity data storage nodes are needed for every K data storage nodes. For example, with 10+4 erasure coding, 4 parity nodes are required for every 10 data nodes. With 3x replication (for example), 14 nodes could store approximately 5 nodes worth of data. With this system, 14 nodes can store 10 nodes worth of data; twice as much. However, since the parity data in this system is stored as extents just like user data, it is not necessary to employ dedicated parity nodes. In fact, having dedicated parity nodes could make implementation of this system more complex than it needs to be. Note that during the very brief period between writing parity extents and removing unneeded replicas, storage will be consumed for both triple replicas and parity data. Storage administrators using embodiments of the present invention in near-full storage clusters need to account for this temporary storage requirement. The amount of storage required will depend on the data write rate. The storage required at various steps of the process are described in Table 1 below.

TABLE 1

| | | Example: 2 GB | |
|---|---|---|---|
| Write Phase | Storage Consumed | extents, 10 + 4 EC | |
| 1 Extent written; | extent size * 3 | 6 | GB |
| K Extents written; | extent size * (k * 3) | 60 | GB |
| Parity extents written; | extent size * (k * 3 + r) | 68 | GB |
| Encoding completed; | extent size * (k + r) | 28 | GB |

When applying embodiments of the present invention to existing data, extent writes are not used as the trigger to perform erasure coding. Instead, the extents to be encoded are discovered and then fed into ROLEC manager 306. Unlike traditional erasure coding methods, there is no need to move existing data since embodiments of the present invention do not affect the on-disk data format of user data.

If extent data is compressed, the k extents making up the erasure coded stripe will no longer be of uniform size. Since uniform strip size is required for erasure coding, additional steps must be taken to erasure code compressed extents. During calculation of parity extents at block 610, the largest of the k extents is identified and for the purposes of parity calculation, all other extents are zero-padded out to the size of the largest extent. The size of the parity extents is therefore the size of the largest extent in the stripe, and this size is stored in streams and extents metadata 304 at block 612.

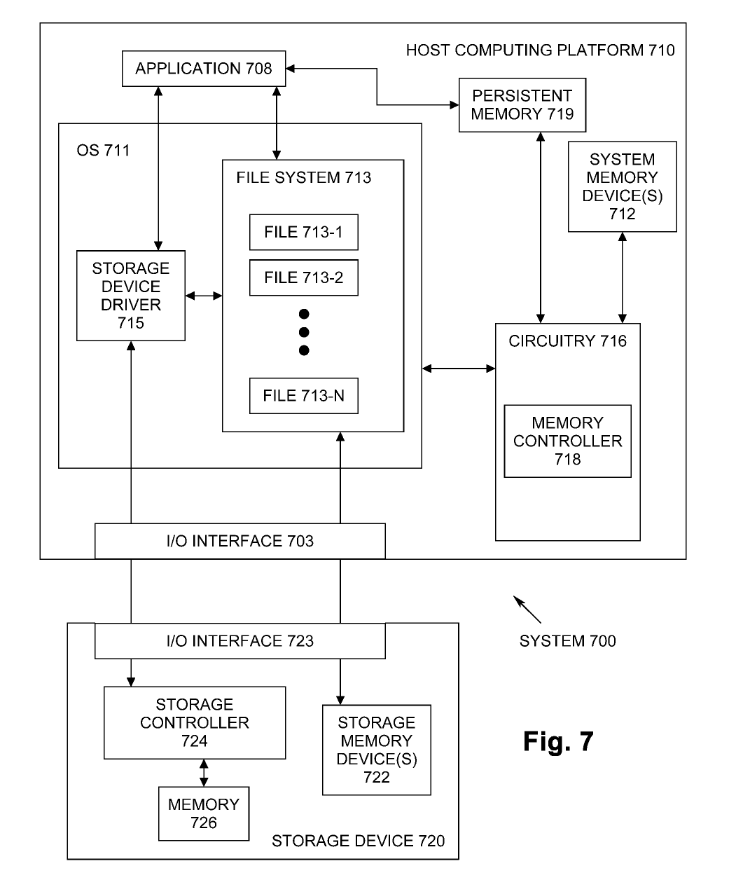

FIG. 7 illustrates an example server computing system 700 in a data center. In some examples, as shown in FIG. 7, system 700 includes a host computing platform (e.g., a server) 710 coupled to one or more storage devices 720 through I/O interface 703 and I/O interface 723. Storage device 720 is representative of any one or more of data storage nodes 210, 212, 214, . . . 216 of FIG. 2. As shown in FIG. 7, server 710 includes an operating system (OS) 711, one or more system memory device(s) 712, circuitry 716 and application 708. For these examples, circuitry 716 is capable of executing various functional elements of server 710 such as OS 711 and/or application 108 and/or storage managers 204, 206, . . . 208 that are maintained, at least in part, within system memory device(s) 712. Circuitry 716 includes host processing circuitry to include one or more central processing units (CPUs) (not shown) and associated chipsets and/or controllers.

According to some examples, as shown in FIG. 7, OS 311 may include file system 713 and one or more storage device drivers 715, and one or more storage devices 720 includes storage controller 724 (which may include one or more processors), one or more storage memory device(s) 722 and memory 726. OS 711 is arranged to implement storage device driver 715 to coordinate at least temporary storage of data for a file from among files 713-1 to 713-n, where “n” is any whole positive integer >1, to storage memory device(s) 722. The data, for example, may have originated from or may be associated with executing at least portions of OS 711 or application 708. As described in more detail below, OS 711 communicates one or more commands and transactions with storage device 720 to write data to or read data from storage device 720. The commands and transactions are organized and processed by logic and/or features at storage device 720 to write the data to or read data from storage device 720.

In some examples, storage controller 724 includes logic and/or features to receive transaction requests to storage memory device(s) 722 at storage device 720. For these examples, the transaction requests are initiated by or sourced from OS 711 that may, in some embodiments, utilize file system 713 to write/read data to/from storage device 720 through input/output (I/O) interfaces 703 and 723. In some embodiments of the present invention, storage controller 724 includes logic and/or features to perform the processing of storage manager I 302 and ROLEC manager 306 as described in FIG. 4 and FIG. 6. In an embodiment, streams and extents metadata 304 is stored in memory 726. In other embodiments of the present invention, the processing steps of storage manager I 302 and ROLEC manager 306 are performed by circuitry 716, and streams and extents metadata 304 are stored in at least one of persistent memory 719 and system memory device(s) 712.

In some examples, memory 726 includes volatile types of memory including, but not limited to, RAM, D-RAM, DDR SDRAM, SRAM, T-RAM or Z-RAM. One example of volatile memory includes DRAM, or some variant such as SDRAM. A memory subsystem as described herein may be compatible with a number of memory technologies, such as DDR4 (DDR version 4, initial specification published in September 2012 by JEDEC), LPDDR4 (LOW POWER DOUBLE DATA RATE (LPDDR) version 4, JESD209-4, originally published by JEDEC in August 2014), WIO2 (Wide I/O 2 (WideIO2), JESD229-2, originally published by JEDEC in August 2014), HBM (HIGH BANDWIDTH MEMORY DRAM, JESD235, originally published by JEDEC in October 2013), DDR5 (DDR version 5, currently in discussion by JEDEC), LPDDR5 (LPDDR version 5, currently in discussion by JEDEC), HBM2 (HBM version 2, currently in discussion by JEDEC), and/or others, and technologies based on derivatives or extensions of such specifications.

However, examples are not limited in this manner, and in some instances, memory 726 includes non-volatile types of memory, whose state is determinate even if power is interrupted to memory 726. In some examples, memory 726 includes non-volatile types of memory that is a block addressable, such as for NAND or NOR technologies. Thus, memory 726 can also include a future generation of types of non-volatile memory, such as a 3-dimensional cross-point memory (3D XPoint™ commercially available from Intel Corporation), or other byte addressable non-volatile types of memory. According to some examples, memory 726 includes types of non-volatile memory that includes chalcogenide glass, multi-threshold level NAND flash memory, NOR flash memory, single or multi-level Phase Change Memory (PCM), a resistive memory, nanowire memory, FeTRAM, MRAM that incorporates memristor technology, or STT-MRAM, or a combination of any of the above, or other memory.

In some examples, storage memory device(s) 722 is a device to store data from write transactions and/or write operations. Storage memory device(s) 722 includes one or more chips or dies having gates that may individually include one or more types of non-volatile memory to include, but not limited to, NAND flash memory, NOR flash memory, 3-D cross-point memory (3D XPoint™), ferroelectric memory, SONOS memory, ferroelectric polymer memory, FeTRAM, FeRAM, ovonic memory, nanowire, EEPROM, phase change memory, memristors or STT-MRAM. For these examples, storage device 720 are arranged or configured as a solid-state drive (SSD). The data is read and written in blocks and a mapping or location information for the blocks may be kept in memory 726.

According to some examples, communications between storage device driver 715 and storage controller 724 for data stored in storage memory devices(s) 722 and accessed via files 713-1 to 713-n is routed through I/O interface 703 and I/O interface 723. I/O interfaces 703 and 723 are arranged as a Serial Advanced Technology Attachment (SATA) interface to couple elements of server 710 to storage device 720. In another example, I/O interfaces 703 and 723 are arranged as a Serial Attached Small Computer System Interface (SCSI) (or simply SAS) interface to couple elements of server 710 to storage device 720. In another example, I/O interfaces 703 and 723 are arranged as a Peripheral Component Interconnect Express (PCIe) interface to couple elements of server 710 to storage device 720. In another example, I/O interfaces 703 and 723 are arranged as a Non-Volatile Memory Express (NVMe) interface to couple elements of server 710 to storage device 720. For this other example, communication protocols are utilized to communicate through I/O interfaces 703 and 723 as described in industry standards or specifications (including progenies or variants) such as the Peripheral Component Interconnect (PCI) Express Base Specification, revision 3.1, published in November 2014 (“PCI Express specification” or “PCIe specification”) or later revisions, and/or the Non-Volatile Memory Express (NVMe) Specification, revision 1.2, also published in November 2014 (“NVMe specification”) or later revisions.

In some examples, system memory device(s) 712 stores information and commands which are used by circuitry 716 for processing information. Also, as shown in FIG. 7, circuitry 716 includes a memory controller 718. Memory controller 718 is arranged to control access to data at least temporarily stored at system memory device(s) 712 for eventual storage to storage memory device(s) 722 at storage device 720.

In some examples, storage device driver 715 includes logic and/or features to forward commands associated with one or more read or write transactions and/or read or write operations originating from OS 711. For example, the storage device driver 715 forwards commands associated with write transactions such that data is caused to be stored to storage memory device(s) 722 at storage device 720.

System Memory device(s) 712 includes one or more chips or dies having volatile types of memory such RAM, D-RAM, DDR SDRAM, SRAM, T-RAM or Z-RAM. However, examples are not limited in this manner, and in some instances, system memory device(s) 712 includes non-volatile types of memory, including, but not limited to, NAND flash memory, NOR flash memory, 3-D cross-point memory (3D XPoint™), ferroelectric memory, SONOS memory, ferroelectric polymer memory, FeTRAM, FeRAM, ovonic memory, nanowire, EEPROM, phase change memory, memristors or STT-MRAM.

Persistent memory 719 includes one or more chips or dies having non-volatile types of memory, including, but not limited to, NAND flash memory, NOR flash memory, 3-D cross-point memory (3D XPoint™), ferroelectric memory, SONOS memory, ferroelectric polymer memory, FeTRAM, FeRAM, ovonic memory, nanowire, EEPROM, phase change memory, memristors or STT-MRAM.

According to some examples, server 710 includes, but is not limited to, a server, a server array or server farm, a web server, a network server, an Internet server, a work station, a mini-computer, a main frame computer, a supercomputer, a network appliance, a web appliance, a distributed computing system, a personal computer, a tablet computer, a smart phone, multiprocessor systems, processor-based systems, or combination thereof, in a data center region.

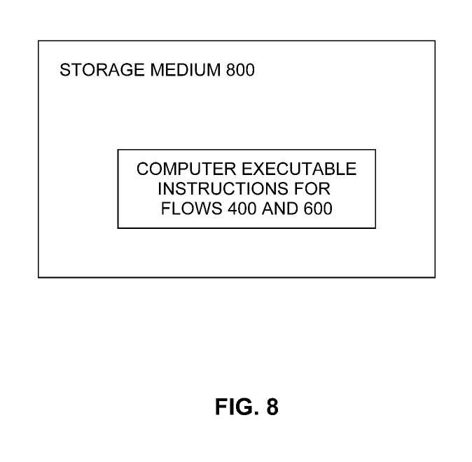

FIG. 8 illustrates an example of a storage medium. The storage medium 800 comprises an article of manufacture. In some examples, storage medium 800 includes any non-transitory computer readable medium or machine readable medium, such as an optical, magnetic or semiconductor storage. Storage medium 800 stores various types of computer executable instructions, such as instructions to implement logic flows described above. Examples of a computer readable or machine-readable storage medium include any tangible media capable of storing electronic data, including volatile memory or non-volatile memory, removable or non-removable memory, erasable or non-erasable memory, writeable or re-writeable memory, and so forth. Examples of computer executable instructions include any suitable type of code, such as source code, compiled code, interpreted code, executable code, static code, dynamic code, object-oriented code, visual code, and the like. The examples are not limited in this context.

According to some examples, at least one of circuitry 716 and storage controller 724 of FIG. 7 executes processing operations or logic for the steps described in FIG. 4 and FIG. 6 and/or storage medium 800. Circuitry 316 and/or storage controller 724 include various hardware elements, software elements, or a combination of both. Examples of hardware elements include devices, logic devices, components, processors, microprocessors, circuits, processor circuits, circuit elements (e.g., transistors, resistors, capacitors, inductors, and so forth), integrated circuits, ASIC, programmable logic devices (PLD), digital signal processors (DSP), FPGA/programmable logic, memory units, logic gates, registers, semiconductor device, chips, microchips, chip sets, and so forth. Examples of software elements include software components, programs, applications, computer programs, application programs, device drivers, system programs, software development programs, machine programs, operating system software, middleware, firmware, software components, routines, subroutines, functions, methods, procedures, software interfaces, application program interfaces (API), instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given example.

Server 710 and storage device 720 are parts of a computing device that may be, for example, user equipment, a computer, a personal computer (PC), a desktop computer, a laptop computer, a notebook computer, a netbook computer, a tablet, a smart phone, embedded electronics, a gaming console, a server array or server farm, a web server, a network server, an Internet server, a work station, a mini-computer, a main frame computer, a supercomputer, a network appliance, a web appliance, a distributed computing system, multiprocessor systems, processor-based systems, or combination thereof. Accordingly, functions and/or specific configurations of server 710 and storage device 720 described herein, may be included or omitted in various embodiments of server 710 and storage device 720, as suitably desired.

The components and features of server 710 and storage device 720 may be implemented using any combination of discrete circuitry, ASICs, logic gates and/or single chip architectures. Further, the features of server 710 and storage device 720 may be implemented using microcontrollers, programmable logic arrays and/or microprocessors or any combination of the foregoing where suitably appropriate. It is noted that hardware, firmware and/or software elements may be collectively or individually referred to herein as “logic”, “circuit” or “circuitry.”

Some examples may be described using the expression “in one example” or “an example” along with their derivatives. These terms mean that a particular feature, structure, or characteristic described in connection with the example is included in at least one example. The appearances of the phrase “in one example” in various places in the specification are not necessarily all referring to the same example.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

It is emphasized that the Abstract of the Disclosure is provided to comply with 37 C.F.R. Section 1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single example for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separate example. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A method comprising:
receiving a request to write a stream of data;
separating the stream into a plurality of extents;
storing a primary replica and one or more additional replicas of each extent of the separated stream to a first plurality of data storage nodes;
updating a list of extents to be erasure encoded; and
when an erasure encoded stripe can be created, getting the data for each of the extents of the erasure encoded stripe, calculating parity extents for unencoded extents of the erasure encoded stripe, writing the parity extents to a second plurality of data storage nodes, and deleting the one or more additional replicas of the extents of the erasure encoded stripe from the first plurality of data storage nodes.

2. The method of claim 1, comprising distributing the primary and one or more additional replicas of the extents across the first plurality of data storage nodes such that no data storage node stores more than one replica of each extent.

3. The method of claim 1, comprising writing the replicas to data storage nodes of different fault domains.

4. The method of claim 1, comprising updating streams and extents metadata with locations of the replicas of each stored extent.

5. The method of claim 4, comprising updating streams and extents metadata for the extents of the stripe after calculating and writing the parity extents and prior to deleting one or more additional replicas.

6. The method of claim 1, comprising performing the updating of the list of extents to be erasure encoded; and when an erasure encoded stripe can be created, the getting of the data for each of the extents of the erasure encoded stripe, the calculating of the parity extents for unencoded extents of the erasure encoded stripe, the writing of the parity extents to the second plurality of data storage nodes, and the deleting one or more additional replicas of the extents of the erasure encoded stripe from the first plurality of data storage nodes, in a different processing thread than the receiving of the request to write a stream of data, the separating of the stream into a plurality of extents, and the storing the primary and one or more additional replicas of each extent of the separated stream to the first plurality of data storage nodes.

7. The method of claim 1, comprising choosing the unencoded extents that make up an erasure encoded stripe such that no data storage node stores more than one unencoded data extent or parity extent of each stripe.

8. The method of claim 1, comprising choosing the unencoded extents that make up an erasure encoded stripe such that each of the data extents and parity extents are stored in data storage nodes of different fault domains.

9. The method of claim 1, comprising writing the parity extents to data storage nodes of different fault domains than other unencoded data extents or parity extents of the erasure encoded stripe.

10. The method of claim 1, comprising reading the extent data from the data storage node storing the primary replica of the extent.

11. The method of claim 1, comprising reconstructing a requested extent from other extents and parity extents of the requested extent's stripe if the primary replica of the requested extent is unavailable.

12. At least one machine readable medium comprising a plurality of instructions that in response to being executed by a system at a computing platform, cause the system to:
separate a received stream of data into a plurality of extents;
store a primary replica and one or more additional replicas of each extent of the separated stream to a first plurality of data storage nodes;
update a list of extents to be erasure encoded; and
when an erasure encoded stripe can be created, get the data for each of the extents of the erasure encoded stripe, calculate parity extents for unencoded extents of the erasure encoded stripe, write the parity extents to a second plurality of data storage nodes, and delete one or more additional replicas of the extents of the erasure encoded stripe from the first plurality of data storage nodes.

13. The at least one machine readable medium of claim 12, comprising instructions to distribute the primary and one or more additional replicas of the extents across the first plurality of data storage nodes such that no data storage node stores more than one replica of each extent.

14. The at least one machine readable medium of claim 12, comprising instructions to write the replicas to data storage nodes of different fault domains.

15. The at least one machine readable medium of claim 12, comprising instructions to update streams and extents metadata with locations of the replicas of each stored extent.

16. The at least one machine readable medium of claim 15, comprising instructions to update streams and extents metadata for the extents of the stripe after calculating and writing the parity extents and prior to deleting one or more additional replicas.

17. The at least one machine readable medium of claim 12, comprising instructions for performing the updating of the list of extents to be erasure encoded; and when an erasure encoded stripe can be created, the getting of the data for each of the extents of the erasure encoded stripe, the calculating of the parity extents for unencoded extents of the erasure encoded stripe, the writing of the parity extents to the second plurality of data storage nodes, and the deleting the one or more additional replicas of the extents of the erasure encoded stripe from the first plurality of data storage nodes, in a different processing thread than the receiving the request to write a stream of data, the separating the stream into a plurality of extents, and the storing of the primary and one or more additional replicas of each extent of the separated stream in the first plurality of data storage nodes.

18. The at least one machine readable medium of claim 12, comprising instructions to choose the unencoded extents that make up an erasure encoded stripe such that no data storage node stores more than one unencoded data extent or parity extent of each stripe.

19. The at least one machine readable medium of claim 12, comprising instructions to choose the unencoded extents that make up an erasure encoded stripe such that each of the data extents and parity extents are stored in data storage nodes of different fault domains.

20. The at least one machine readable medium of claim 12, comprising instructions to write the parity extents to data storage nodes of different fault domains than unencoded data extents or other parity extents of the erasure encoded stripe.

21. An apparatus comprising:
a storage manager to receive a request to write a stream of data, to separate the stream into a plurality of extents, and to store a primary replica and one or more additional replicas of each extent of the separated stream to a first plurality of data storage nodes; and
an erasure encoding manager coupled to the storage manager to update a list of extents to be erasure encoded, and when an erasure encoded stripe can be created, get the data for each of the extents of the erasure encoded stripe, calculate parity extents for unencoded extents of the erasure encoded stripe, write the parity extents to a second plurality of data storage nodes, and delete the one or more additional replicas of the extents of the erasure encoded stripe from the first plurality of data storage nodes.

22. The apparatus of claim 21, wherein the storage manager to distribute the primary and one or more additional replicas of the extents across the first plurality of data storage nodes such that no data storage node stores more than one replica of each extent.

23. The apparatus of claim 21, comprising storage manager to write the replicas to data storage nodes of different fault domains.

24. The apparatus of claim 23, comprising the storage manager to update streams and extents metadata for the extents of the stripe after calculating and writing the parity extents and prior to deleting the one or more additional replicas.

25. The apparatus of claim 21, wherein the storage manager executes in a different processing thread than the erasure encoding manager.
